(19) United States
(12) Patent Application Publication
(10) Pub. No.: US 2022/0146580 A1
(43) Pub. Date: May 12, 2022

(54) COIN BATTERY TESTING DEVICE

(71) Applicant: FlowVIEW Tek, Taipei City (TW)

(72) Inventors: Po-Yang Peng, Taipei City (TW); Chun-Chieh Liang, Taipei City (TW); Min-Chuan Shih, Taipei City (TW); Cheng-Yu Lee, Taipei City (TW); Hsin-Hung Lee, Taipei City (TW)

(73) Assignee: FlowVIEW Tek, Taipei City (TW)

(21) Appl. No.: 17/499,827

(22) Filed: Oct. 12, 2021

Related U.S. Application Data
(60) Provisional application No. 63/113,173, filed on Nov. 12, 2020.

(30) Foreign Application Priority Data
Jun. 23, 2021 (TW) 110122956

(51) Int. Cl. G01R 31/36

(52) U.S. Cl. CPC G01R 31/3644

(57) ABSTRACT

A coin battery testing device, including a bottom base, an upper cover, a positive conducting structure, and a negative conducting structure, is provided. The bottom base has an observation region and is adapted to carry a coin battery by the observation region. The upper cover is detachably connected to the bottom base and adapted to cover the coin battery on the observation region. The upper cover has an opening and the opening corresponds to the observation region, such that the coin battery is adapted to be observed through the opening. The positive conducting structure is disposed on the bottom base and adapted to be connected to a positive electrode of the coin battery on the observation region. The negative conducting structure is disposed on the bottom base and adapted to be connected to a negative electrode of the coin battery on the observation region.

### CROSS-REFERENCE TO RELATED APPLICATION

This application claims the priority benefit of U.S. Provisional Application No. 63/113,173, filed on Nov. 12, 2020 and Taiwan Application No. 110122956, filed on Jun. 23, 2021. The entirety of each of the above-mentioned patent applications is hereby incorporated by reference herein and made a part of this specification.

### BACKGROUND

### Technical Field

The invention relates to a battery testing device, and particularly relates to a coin battery testing device.

### Description of Related Art

A coin battery needs to go through a power-on test to confirm whether its function is normal. A current testing method on the market is to stack multiple layers of materials on a testing device and conduct electrical tests in a simulated manner. This type of assembled and packaged coin battery is a mature technology, and in an assembling and packaging process, a user controls and defines conditions for assembling and packaging the batteries, such as a packaging pressure, a time, a temperature, . . . , etc., other than directly using real coin batteries for testing. This test method requires tedious material stacking and assembling operations, and is more labor-intensive and time-consuming.

### SUMMARY

The invention is directed to a coin battery testing device, which is adapted to simplify a testing process.

The invention provides a coin battery testing device including a bottom base, an upper cover, a positive conducting structure and a negative conducting structure. The bottom base has an observation region and is adapted to carry a coin battery by the observation region. The upper cover is detachably connected to the bottom base and adapted to cover the coin battery on the observation region. The upper cover has an opening, and the opening corresponds to the observation region, such that the coin battery is adapted to be observed through the opening. The positive conducting structure is disposed on the bottom base and adapted to be connected to a positive electrode of the coin battery on the observation region. The negative conducting structure is disposed on the bottom base and adapted to be connected to a negative electrode of the coin battery on the observation region.

In an embodiment of the invention, the bottom base includes a base body and a carrier, and the carrier is disposed on the base body to form the observation region. The carrier has an accommodating groove suitable for accommodating the coin battery.

In an embodiment of the invention, the positive conducting structure is disposed on the carrier and has a conducting portion and a terminal portion opposite to each other, the conducting portion is located at a top of the accommodating groove and is adapted to be connected to the positive electrode of the coin battery on the observation region, and the terminal portion is located on a lower surface of the carrier.

In an embodiment of the invention, the negative conducting structure is disposed on the carrier and has a conducting portion and a terminal portion opposite to each other, the conducting portion is located on an upper surface of the carrier and is adapted to be connected to the negative electrode of the coin battery on the observation region, and the terminal portion is located on a bottom surface of the carrier.

In an embodiment of the invention, the carrier has at least one sidewall portion, and the at least one sidewall portion surrounds the accommodating groove.

In an embodiment of the invention, the coin battery testing device includes a sealing ring, wherein the sealing ring is disposed on the bottom base and surrounds the observation region, and the upper cover is tightly leaned against the sealing ring.

In an embodiment of the invention, the upper cover includes a cover body and a position limiting assembly, the cover body is adapted to cover the coin battery on the observation region, the opening is formed in the cover body, and the position limiting assembly is detachably assembled on the bottom base and limits a position of the cover body on the bottom base.

In an embodiment of the invention, the bottom base includes a base body and at least one locking portion, the at least one locking portion is connected to the base body, the position limiting assembly has at least one slot, and the at least one locking portion is adapted to pass through the at least one slot and lock the position limiting assembly.

In an embodiment of the invention, the slot includes a releasing section and a locking section connected to each other, the at least one locking portion includes a head portion and a neck portion, the neck portion is connected between the base body and the head portion, a width of the releasing section is greater than an outer diameter of the head portion, the outer diameter of the head portion is greater than a width of the locking section, the width of the locking section is greater than an outer diameter of the neck portion, the head portion is adapted to pass through the at least one slot through the releasing section, and the position limiting assembly is adapted to be rotated relative to the bottom base to drive the at least one locking portion to move from the releasing section to the locking section.

In an embodiment of the invention, a number of the at least one locking portion is plural, and the locking portions surround the observation region.

Based on the above description, in the coin battery testing device of the invention, a real coin battery is adapted to be directly mounted between the bottom base and the upper cover, and a power-on test is performed on the coin battery through the positive conducting structure and the negative conducting structure provided on the bottom base, and the power-on coin battery may be observed by an optical microscope, an electron microscope or other types of observation equipment through the opening of the upper cover. In this way, an external dedicated assembling and packaging equipment is used to complete assembling the coin battery, so that it is unnecessary to stack multiple layers of battery materials on the testing device in a simulated manner, which saves a time and a process required for stacking, assembling and packaging the battery materials during testing, and reduces a difference of stacking assembling when different operators perform testing. In addition, the coin battery testing device of the invention may uniformize the battery assembling conditions, and may test coin batteries with assembling conditions of different assembling and packaging equipment, so as to increase an application level of the testing device.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a three-dimensional view of a coin battery testing device according to an embodiment of the invention.

FIG. 2 is an exploded view of the coin battery testing device of FIG. 1.

FIG. 3 illustrates a partial structure of the coin battery testing device of FIG. 1.

### DESCRIPTION OF THE EMBODIMENTS

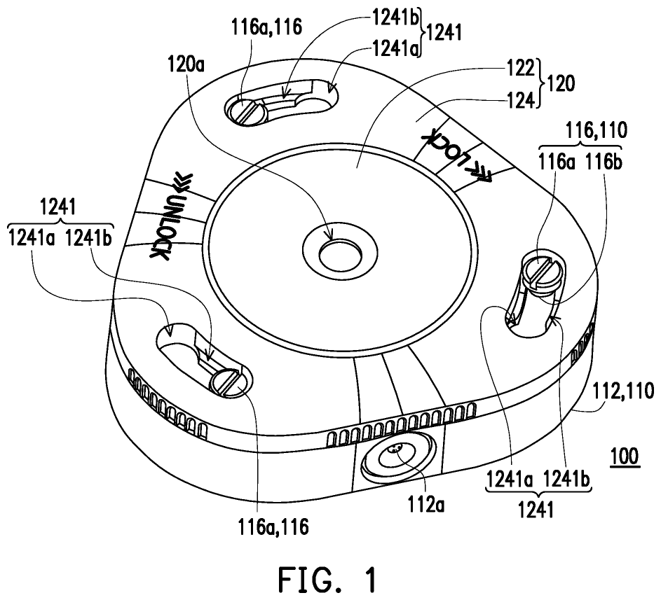

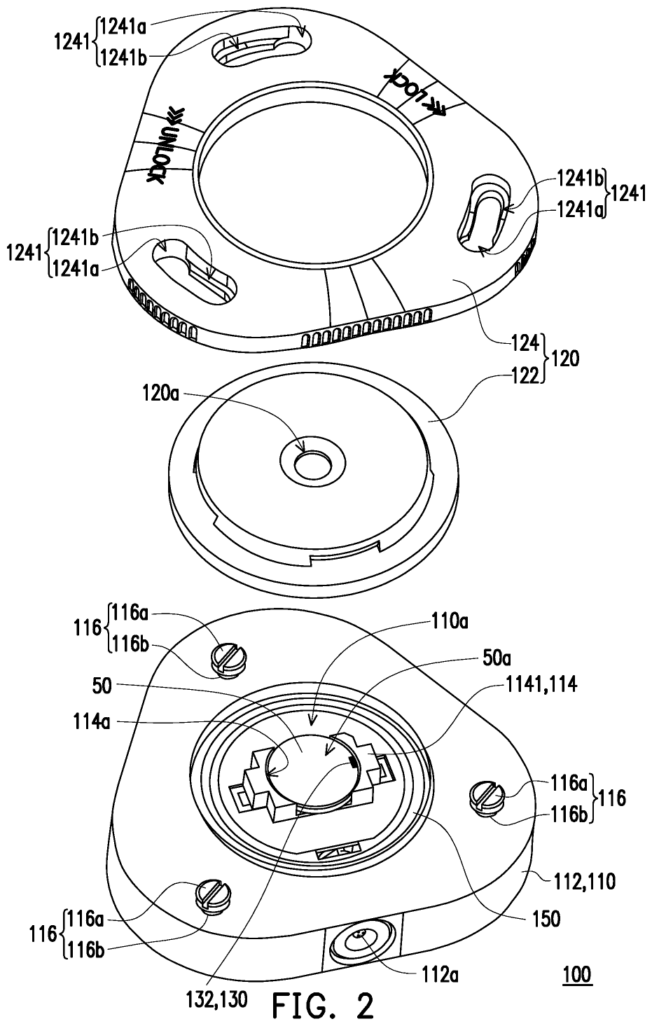

FIG. 1 is a three-dimensional view of a coin battery testing device according to an embodiment of the invention. FIG. 2 is an exploded view of the coin battery testing device of FIG. 1. Referring to FIG. 1 and FIG. 2, a coin battery testing device 100 of the embodiment includes a bottom base 110 and an upper cover 120. The bottom base 110 has an observation region 110a and is adapted to carry a coin battery 50 by the observation region 110a. The upper cover 120 is detachably connected to the bottom base 110 and is adapted to cover the coin battery 50 on the observation region 110a. The upper cover 120 has an opening 120a, and the opening 120a corresponds to the observation region 110a, such that the coin battery 50 is adapted to be observed through the opening 120a.

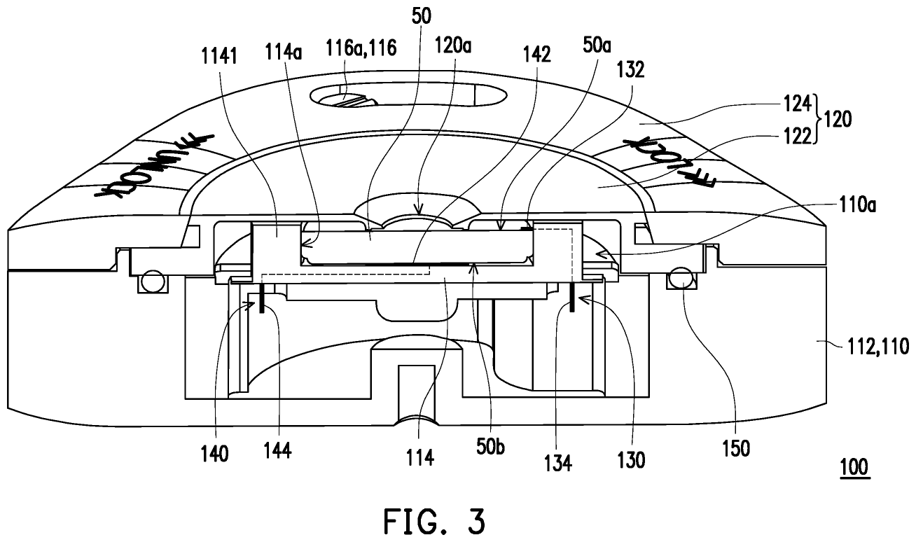

FIG. 3 illustrates a partial structure of the coin battery testing device of FIG. 1. Referring to FIG. 3, the coin battery testing device 100 further includes a positive conducting structure 130 and a negative conducting structure 140. The positive conducting structure 130 is disposed on the bottom base 110 and is adapted to be connected to a positive electrode 50a of the coin battery 50 on the observation region 110a, and the negative conducting structure 140 is disposed on the bottom base 110 and is adapted to be connected to a negative electrode 50b of the coin battery 50 on the observation region 110a.

Under the above configuration, the real coin battery 50 may be directly installed between the bottom base 110 and the upper cover 120 of the coin battery testing device 100, and a power-on test may be performed on the coin battery 50 through the positive conducting structure 130 and the negative conducting structure 140 provided on the bottom base 110, and the power-on coin battery 50 may be observed by an optical microscope, an electron microscope or other types of observation equipment through the opening 120a of the upper cover 120. In this way, it is unnecessary to stack multiple layers of battery materials on the testing device in a simulated manner, which simplifies a testing flow. In addition, in the embodiment, the positive conducting structure 130 and the negative conducting structure 140 are both disposed on the bottom base 110 instead of being separately disposed on the bottom base 110 and the upper cover 120, so that the upper cover 120 is a simple structural member and does not include a conducting structure, which simplifies a manufacturing process of the upper cover 120.

In detail, the bottom base 110 of the embodiment includes a base body 112 and a carrier 114, and the carrier 114 is disposed on the base body 112 to form the observation region 110a. In addition, the carrier 114 has at least one sidewall portion 1141, and the sidewall portion 1141 surrounds an accommodating groove 114a, and the accommodating groove 114a is suitable for accommodating the coin battery 50.

According to the above description, the positive conducting structure 130 is disposed on the carrier 114 and has a conducting portion 132 and a terminal portion 134 opposite to each other, the conducting portion 132 is located at a top of the accommodating groove 114a and is adapted to be connected to the positive electrode 50a of the coin battery 50 on the observation region 110a, and the terminal portion 134 is located on a lower surface of the carrier 114 and may be connected to an electrical connection portion 112a of the base body 112 through a wire or a suitable conducting assembly. Similarly, the negative conducting structure 140 is disposed on the carrier 114 and has a conducting portion 142 and a terminal portion 144 opposite to each other, the conducting portion 142 is located on an upper surface of the carrier 114 and is adapted to be connected to the negative electrode 50b of the coin battery 50 on the observation region 110a, and the terminal portion 144 is located on the bottom surface of the carrier 114 and may be connected to the electrical connection portion 112a of the base body 112 through a wire or a suitable conducting assembly. The electrical connection portion 112a is used for plugging to an external power supply to provide a test current to the coin battery testing device 100. In FIG. 3, a part of the positive conducting structure 130 and a part of the negative conducting structure 140 are schematically shown as extending inside the carrier 114, and an extending method thereof may be changed according to an actual structural design requirement, which is not limited by the invention.

In the embodiment, the coin battery testing device 100 further includes a sealing ring 150 as shown in FIG. 2 and FIG. 3. The sealing ring 150 is, for example, a rubber ring or other elastic sealing material, which is disposed on the base body 112 of the bottom base 110 and surrounds the observation region 110a. The upper cover 120 tightly leans against the sealing ring 150 to isolate the coin battery 50 on the observation region 110a from the outside to facilitate the testing.

The upper cover 120 of the embodiment includes a cover body 122 and a position limiting assembly 124. The cover body 122 is adapted to cover the coin battery 50 on the observation region 110a, and the opening 12a used for exposing the coin battery 50 is formed in the cover body 122. The position limiting assembly 124 is detachably assembled on the base body 112 of the bottom base 110 and limits a position of the cover body 122 on the base body 112 of the bottom base 110.

In detail, the bottom base 110 of the embodiment further includes a plurality of locking portions 116, and the locking portions 116 are connected to the base body 112 and surround the observation region 110a. Correspondingly, the position limiting assembly 124 has a plurality of slots 1241, and each locking portion 116 is adapted to pass through the corresponding slot to lock the position limiting assembly 124.

To be specific, each of the slots 1241 includes a releasing section 1241a and a locking section 1241b connected to each other. Each locking portion 116 includes a head portion 116a and a neck portion 116b, and the neck portion 116b is connected between the base body 112 and the head portion 116a. A width of the releasing section 1241a is greater than an outer diameter of the head portion 116a, the outer diameter of the head portion 116a is greater than a width of the locking section 1241b, and the width of the locking section 1241b is greater than an outer diameter of the neck portion 116b. In this way, the head portion 116a is adapted to pass through the corresponding slot 1241 through the releasing section 1241a, and the position limiting assembly 124 may be rotated relative to the bottom base 110 to drive each locking portion 116 to move from the releasing section 1241a to the locking section 1241b, such that the position limiting assembly 124 is locked by the head portions 116a of the locking portions 116. When the upper cover 110 is to be disassembled, as long as the position limiting assembly 124 is rotated reversely to move each locking portion 116 from the locking section 1241b to the releasing section 1241a, the head 116a of each locking portion 116 may be separated from the corresponding slot 1241 through the releasing section 1241a. Therefore, the cover body 122 and the position limiting assembly 124 may be moved away from the base body 112, and the coin battery 50 that has been tested may be taken out from the observation region 110a or the coin battery 50 to be tested may be placed in the observation region 110a.

In summary, in the coin battery testing device of the invention, a real coin battery may be directly mounted between the bottom base and the upper cover, and the power-on test is performed on the coin battery through the positive conducting structure and the negative conducting structure provided on the bottom base, and the power-on coin battery may be observed by an optical microscope, an electron microscope or other types of observation equipment through the opening of the upper cover. In this way, it is unnecessary to stack multiple layers of battery materials on the testing device in a simulated manner, which simplifies a testing process. In addition, in the invention, the positive conducting structure and the negative conducting structure are both disposed on the bottom base, instead of being separately arranged on the bottom base and the upper cover, so that the upper cover is a simple structural member and does not include a conducting structure, which simplifies a manufacturing process of the upper cover.

What is claimed is:

1. A coin battery testing device, comprising:
a bottom base, having an observation region and adapted to carry a coin battery by the observation region;
an upper cover, detachably connected to the bottom base and adapted to cover the coin battery on the observation region, wherein the upper cover has an opening, and the opening corresponds to the observation region, such that the coin battery is adapted to be observed through the opening;
a positive conducting structure, disposed on the bottom base and adapted to be connected to a positive electrode of the coin battery on the observation region; and
a negative conducting structure, disposed on the bottom base and adapted to be connected to a negative electrode of the coin battery on the observation region.

2. The coin battery testing device as claimed in claim 1, wherein the bottom base comprises a base body and a carrier, the carrier is disposed on the base body to form the observation region, and the carrier has an accommodating groove suitable for accommodating the coin battery.

3. The coin battery testing device as claimed in claim 2, wherein the positive conducting structure is disposed on the carrier and has a conducting portion and a terminal portion opposite to each other, the conducting portion is located at a top of the accommodating groove and is adapted to be connected to the positive electrode of the coin battery on the observation region, and the terminal portion is located on a lower surface of the carrier.

4. The coin battery testing device as claimed in claim 2, wherein the negative conducting structure is disposed on the carrier and has a conducting portion and a terminal portion opposite to each other, the conducting portion is located on an upper surface of the carrier and is adapted to be connected to the negative electrode of the coin battery on the observation region, and the terminal portion is located on a bottom surface of the carrier.

5. The coin battery testing device as claimed in claim 2, wherein the carrier has at least one sidewall portion, and the at least one sidewall portion surrounds the accommodating groove.

6. The coin battery testing device as claimed in claim 1, further comprising a sealing ring, wherein the sealing ring is disposed on the bottom base and surrounds the observation region, and the upper cover is tightly leaned against the sealing ring.

7. The coin battery testing device as claimed in claim 1, wherein the upper cover comprises a cover body and a position limiting assembly, the cover body is adapted to cover the coin battery on the observation region, the opening is formed in the cover body, and the position limiting assembly is detachably assembled on the bottom base and limits a position of the cover body on the bottom base.

8. The coin battery testing device as claimed in claim 7, wherein the bottom base comprises a base body and at least one locking portion, the at least one locking portion is connected to the base body, the position limiting assembly has at least one slot, and the at least one locking portion is adapted to pass through the at least one slot and lock the position limiting assembly.

9. The coin battery testing device as claimed in claim 8, wherein the at least one slot comprises a releasing section and a locking section connected to each other, the at least one locking portion comprises a head portion and a neck portion, the neck portion is connected between the base body and the head portion, a width of the releasing section is greater than an outer diameter of the head portion, the outer diameter of the head portion is greater than a width of the locking section, the width of the locking section is greater than an outer diameter of the neck portion, the head portion is adapted to pass through the at least one slot through the releasing section, and the position limiting assembly is adapted to be rotated relative to the bottom base to drive the at least one locking portion to move from the releasing section to the locking section.

10. The coin battery testing device as claimed in claim 8, wherein a number of the at least one locking portion is plural, and the locking portions surround the observation region.
